(19) United States
(12) Patent Application Publication
(10) Pub. No.: US 2013/0147570 A1
(43) Pub. Date: Jun. 13, 2013

(54) METHODS AND APPARATUS FOR LOAD INTERROGATION USING POWER USAGE MODULATION

(71) Applicants: Swen ANDERSON, Limbach-Oberfrohna (DE); Christian Paetz, Zwickau (DE)

(72) Inventors: Swen ANDERSON, Limbach-Oberfrohna (DE); Christian Paetz, Zwickau (DE)

(73) Assignee: Raritan Americas, Inc., Somerset, NJ (US)

(21) Appl. No.: 13/315,317

(22) Filed: Dec. 9, 2011

(51) Int. Cl. H03K 7/02

(52) U.S. Cl. 332/115

(57) ABSTRACT

Methods and apparatus provide for: detecting an identification (ID) number associated with a piece of information technology (IT) equipment using a first computer-readable and executable program running on the piece of IT equipment; modulating a power usage of the piece of IT equipment as a function of the ID number using the first program running on the piece of IT equipment; monitoring the power usage of the piece of IT equipment using a power distribution unit (PDU) that provides operating power to the piece of IT equipment; and detecting modulation in the power usage of the piece of IT equipment caused by the first program running on the piece of IT equipment, such detection being performed using a second computer-readable and executable program running on the PDU.

### BACKGROUND

The invention relates to methods and apparatus for controlling the delivery of power to a load, and more particularly relates to power delivery and control techniques that provide identification information as to the load by analysis of the power drawn thereby.

Information technology (IT) equipment rooms (also known as data centers) utilize tens, hundreds, or even thousands of units of IT equipment. Each piece of IT equipment receives primary power by plugging into an outlet of a power distribution unit (“PDU”). A PDU typically includes: (a) a high power inlet from which power is received (typically from a panel board or a mains supply); (b) multiple lower power outlets or receptacles; and (c) (optional) circuit breakers or fuses to protect the outlets from over current conditions (short circuits, etc.).

PDUs may also provide metering capability, whereby they are often designed to report certain status information over a communication and/or input/output interface, including: (a) the voltage being supplied to a given PDU; (b) how much power is drawn by the inlet and/or from each outlet of a PDU; and (c) the trip state (whether voltage is present) of each circuit breaker. Additionally, PDUs may be switchable, whereby they include the capability of turning on and off the output voltage/current at each outlet receptacle, or at respective groups of receptacles in response to micro-controller signaling. This capability permits some level of software control over the power being delivered from each outlet of the PDU to much, if not most, of the of the IT equipment.

In order for the data gathered through the metering and/or switching functionality to be of most use, there should be some level of confidence that known pieces of IT equipment are connected to known PDU's and/or known outlets of particular PDUs. If such confidence exits, then conclusions may be made as to the status of a particular piece of IT equipment based on the gathered data. Without such confidence, the gathered data may only be regarded a general information and of questionable value as to the status of a particular piece of IT equipment. In order to attain such confidence, conventional methods require a manual process of inspecting the connections between the outlets of a PDU and each piece of IT equipment drawing power therefrom. Identification numbers (e.g., serial numbers, Ethernet MAC addresses, etc.) of the IT equipment may be associated with identification numbers of the PDU and/or the particular outlets thereof so that the data gathered through metering may be properly analyzed and associated with particular pieces of IT equipment.

Among the problems with the manual approach to associating IT equipment with PDUs are the potential for error and the cost associated with conducting the investigation. These problems are exacerbated in environments where there are thousands of units of IT equipment and hundreds or thousands of PDUs. There are, therefore, needs in the art for new methods and apparatus for controlling power delivery to loads in the IT context, which address the problems discussed above.

### SUMMARY OF THE INVENTION

Methods and apparatus provide for: detecting an identification (ID) number associated with a piece of information technology (IT) equipment using a first computer-readable and executable program running on the piece of IT equipment; and modulating a power usage of the piece of IT equipment as a function of the ID number using the first program running on the piece of IT equipment.

The step of modulating may include causing the power usage of the piece of IT equipment to increase and decrease to represent respective characters or groups of characters of the ID number. For example, the characters of the ID number may include a plurality of logic bits, which include logic 1's and 0's; and the step of modulating may include causing the power usage of the piece of IT equipment to increase and decrease to represent the respective bits or groups of bits of the ID number. Further, the step of modulating may include causing the power usage of the piece of IT equipment to: increase and decrease in a first predetermined pattern to represent a logic 1; and increase and decrease in a second predetermined pattern to represent a logic 0.

By way of example, the step of modulating the power usage of the piece of IT equipment as a function of the ID number may include correspondingly causing a usage level of one or more circuits of the piece of IT equipment to increase and decrease using the first program running on the piece of IT equipment. For example, the one or more circuits may include one of more central processing units (CPU's) of the piece of IT equipment.

In accordance with further aspects, methods and apparatus may provide for: monitoring the power usage of the piece of IT equipment using a power distribution unit (PDU) that provides operating power to the piece of IT equipment; and detecting modulation in the power usage of the piece of IT equipment caused by the first program running on the piece of IT equipment, such detection being performed using a second computer-readable and executable program running on the PDU.

The methods and apparatus may further provide for detecting the ID number associated with the piece of IT equipment by analyzing the modulation in the power usage using the second program. Once the ID number is detected, the process may automatically associate the ID number of the piece of IT equipment with the PDU or a particular power output receptacle of the PDU; and preferably store data indicative of the association of the ID number and the PDU, or the particular power output receptacle of the PDU, in a computer-readable storage medium using the second program.

Other aspects, features, and advantages of the present invention will be apparent to one skilled in the art from the description herein taken in conjunction with the accompanying drawings.

### BRIEF DESCRIPTION OF THE DRAWINGS

For the purposes of illustration, there are forms shown in the drawings that are presently preferred, it being understood, however, that the invention is not limited to the precise arrangements and instrumentalities shown.

FIG. 1 is a block diagram of a system for controlling power delivery to a load using a power distribution unit in accordance with one or more embodiments of the present invention;

FIG. 2 illustrates block diagrams of certain computer-implemented portions of the system of FIG. 1;

FIG. 3 is a flow diagram of a data gathering and interrogation process that may be conducted using the system of FIG. 1;

FIG. 4 is a diagram showing a data protocol that may be used in the process of FIG. 3 and the system of FIG. 1; and

FIG. 5 illustrates timing diagrams showing relationships between processing usage in a load (e.g., a piece of IT equipment) as compared with the power drawn by such load from a source (e.g., a PDU), where such processing usage has been modulated through a software program running on the load.

### DETAILED DESCRIPTION OF PREFERRED EMBODIMENTS

Although one or more embodiments of the invention may be designed for use in a PDU and/or a piece of IT equipment, such is not required. Various aspects of the invention are suitable for use in any application where the control of power to a load is provided.

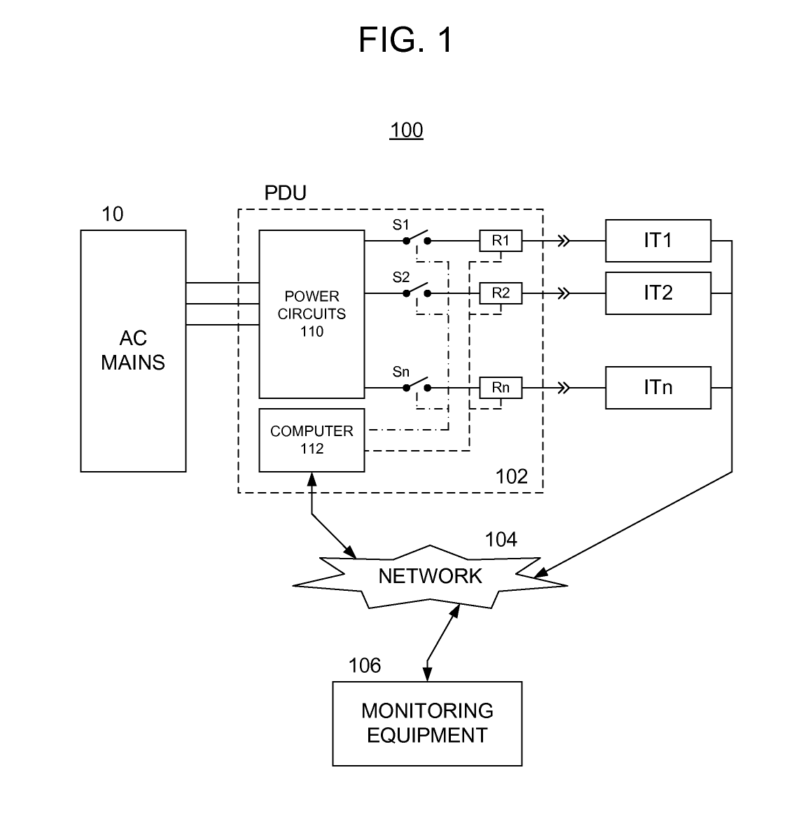

Reference is now made to FIG. 1, which is a block diagram of a system 100 for controlling power delivery to a number of loads. This embodiment is given, by way of example, in the IT context, whereby a PDU 102 provides operating power to one or more pieces of IT equipment, IT1, IT2, . . . ITn. The PDU 102 receives input power from a suitable source, such as AC mains 10. The PDU 102 is operable to communicate over a data network 104, such as a LAN or a WAN (e.g., the Internet), with one or more pieces of monitoring equipment 106. As will be discussed in more detail below, the system 100 operates in accordance with certain techniques that permit the PDU to collect certain status information regarding one or more of the loads IT1, IT2, . . . ITn, such as identification information, confirmation of the connection(s) between the PDU 102 and the one or more loads—all through analysis of the power drawn by such load(s).

The PDU 102 converts the input power from the AC mains 10 to a level of power suitable for operating the loads IT1, IT2, . . . ITn. For example, the input power may multi-phase power and the output power may be a plurality of single-phase outputs, such as 120 VAC outputs. The power conversion from input power to output power is accomplished primarily by the power circuits 110 of the PDU 102, using conventional circuitry and techniques well known in the art. The output power from the power circuits 110 may be switched via one or more switching circuits, schematically illustrated as single pole, single throw, switches S1, S2, . . . Sn. The switching circuits S1, S2, . . . Sn may be controlled via computer 112 using conventional circuits and techniques well known in the art. Although not explicitly illustrated, there may be over-current protection, over-voltage protection, ground fault protection and/or other forms of power conditioning and/or control employed within the PDU 102.

The output power from the switching circuits S1, S2, . . . Sn is delivered to the IT equipment IT1, IT2, . . . ITn via receptacles R1, R2, . . . Rn. Metering circuitry is included within the power circuits 110, the switching circuits S1, S2, . . . Sn and/or the receptacles R1, R2, . . . Rn to provide certain information to the computer 112, such as: (i) the voltage and/or current characteristics of the input power being supplied to the PDU 102; (ii) the voltage and/or current characteristics of the power drawn through each receptacle to each piece of IT equipment IT1, IT2, . . . ITn; and (iii) the state of each switching circuit, ground fault circuit, etc. The specific hardware and/or software required to implement the basic metering functionality is conventional and well known in the art.

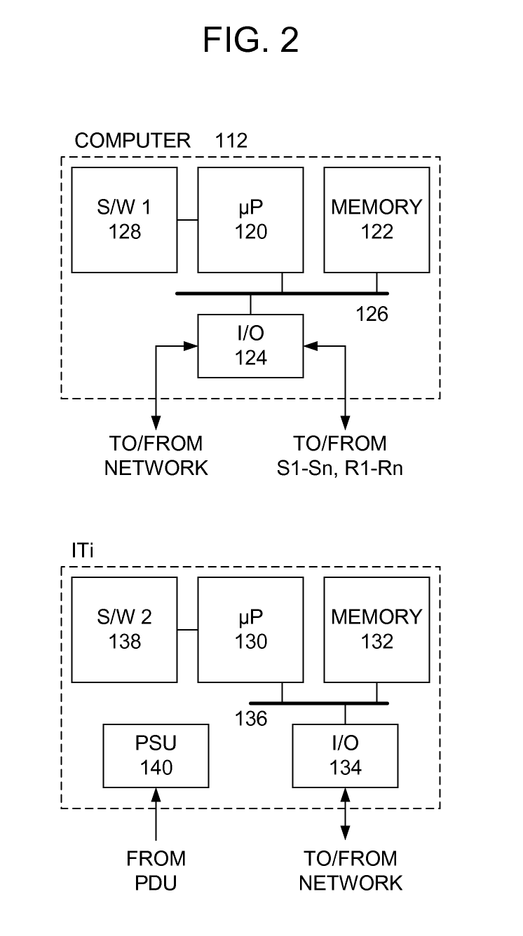

With reference to FIG. 2, the computer 112 of the PDU 102 includes one or more microprocessors 120, one or more computer-readable storage media (memories) 122, and input/output circuitry 124, which are in communication with one another over a data bus 126. The input/output circuitry 124 may provide data and/or control communication between the computer 112 and any number of circuits within the PDU 102. For example, control signals may be provided to the switching circuits S1, S2, . . . Sn to turn on and off power to a particular load ITi. Alternatively or additionally, certain data (such as metering data) may be obtained from voltage and/or current sensors (and/or other types of sensors) within the PDU 102 and provided to the computer 112 via the input/output circuit 124. The input/output circuitry 124 also permits data communications between the computer 112 and the network 104, for example in order to send metering data (and/or other data) to the monitoring equipment 106 and/or to receive commands or other information into the PDU 102. The PDU 126 also includes a software program 128, which is illustrated schematically as being a separate functional unit, but may be integrated with one or more of the other functional blocks, such as the memory 122. Details of the software program 128 are of importance in understanding various aspects of the invention and will be discussed in more detail later in this description. It is understood that the particular boundaries of the functional blocks illustrated in FIG. 2 are provided by way of example only; indeed, many variations of the boundaries of such functions are possible as would be apparent to a skilled artisan given the disclosure herein.

One or more of the loads ITi may also include one or more microprocessors 130, one or more memories 132, and input/output circuitry 134, which are in communication with one another over a data bus 136. The load ITi also includes a power supply circuit 140 that receives operating power from the PDU 102, conditions the power, and delivers operating power to various circuits within the load ITi, such as the aforementioned microprocessors 130, memories 132, input/output circuitry 134, etc. The input/output circuitry 134 permits data communications between the load ITi and the network 104 (and/or other communications channels, not shown), as would be understood by skilled artisans. The load ITi also includes a software program 138, which again is illustrated schematically as being a separate functional unit, but may be integrated with one or more of the other functional blocks, such as the memory 132. As with the software program 128 of the computer 112, details of the software program 138 are of importance in understanding various aspects of the invention and will be discussed in more detail later in this description. Also, the particular boundaries of the functional blocks within the load ITi are provided by way of example only, and many variations of such boundaries are available to the artisan.

As mentioned earlier, the system 100 operates in accordance with certain techniques that permit the PDU 102 to collect certain status information regarding one or more of the loads ITi through analysis of the power drawn by such load(s). Such functionality is achieved by way of the software programs 128, 138 resident on the PDU 102 and the ITi, respectively. It is understood that, although a software implementation is preferred, alternative implementations are possible, such as a firmware implementation or a fully or substantially fully hardware implementation.

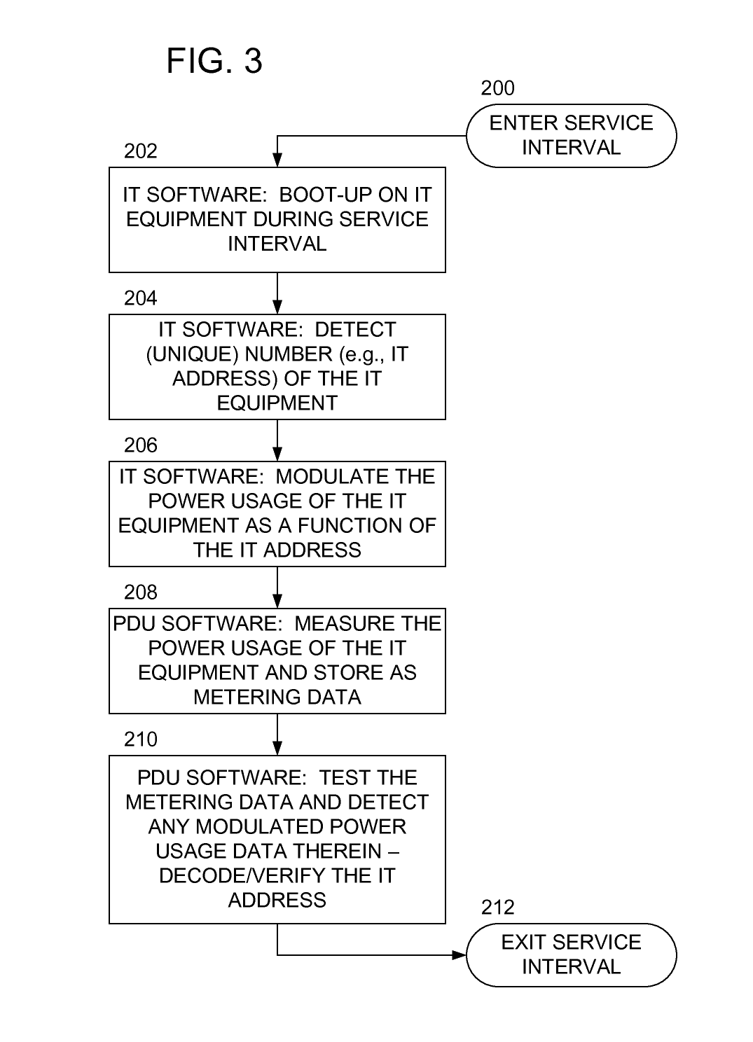

Irrespective of the particular implementation, the process flow carried out by the software programs 128, 138, in association with the respective computing hardware/firmware executing same, is illustrated in the flow diagram of FIG. 3. It is believed that in certain circumstances the execution of certain portions of the process may interrupt or otherwise disrupt the normal operation of the piece of IT equipment, ITi, at issue and, thus, may inhibit the production environment. In such circumstances, it is preferred that the process invoked by the software 138 running on the load ITi be executed during a service interval (action 200). In this way, the load ITi is temporarily taken out of the production environment and any undesired consequences of an uncontrolled interruption thereof are avoided. Although the software 138 may be invoked in any number of ways, it is preferred that such software is provided by way of a bootable operating system image, which is booted during the service interval (action 202).

Once invoked, the software 138 may cause various circuits within the load ITi to carry out actions in order to achieve some desirable functionality. Among these actions is to detect an identification (ID) number associated with the piece of IT equipment, ITi. Such ID number may be stored within the load ITi and may be computer-readable in any number of ways, such as via ROM, hardware register(s), e-fuse(s), etc. While the ID number may take on many forms, it is preferred that the ID number be at least somewhat unique in the context of the overall system 100, such as would be provided by a serial number, an Ethernet MAC address of the load, and/or some other suitable identifier. An advantage of utilizing the Ethernet MAC address of the load ITi as the ID number is that such address is fairly long (48 bits) and guaranteed by the MAC protocol scheme of IEEE to be unique, worldwide.

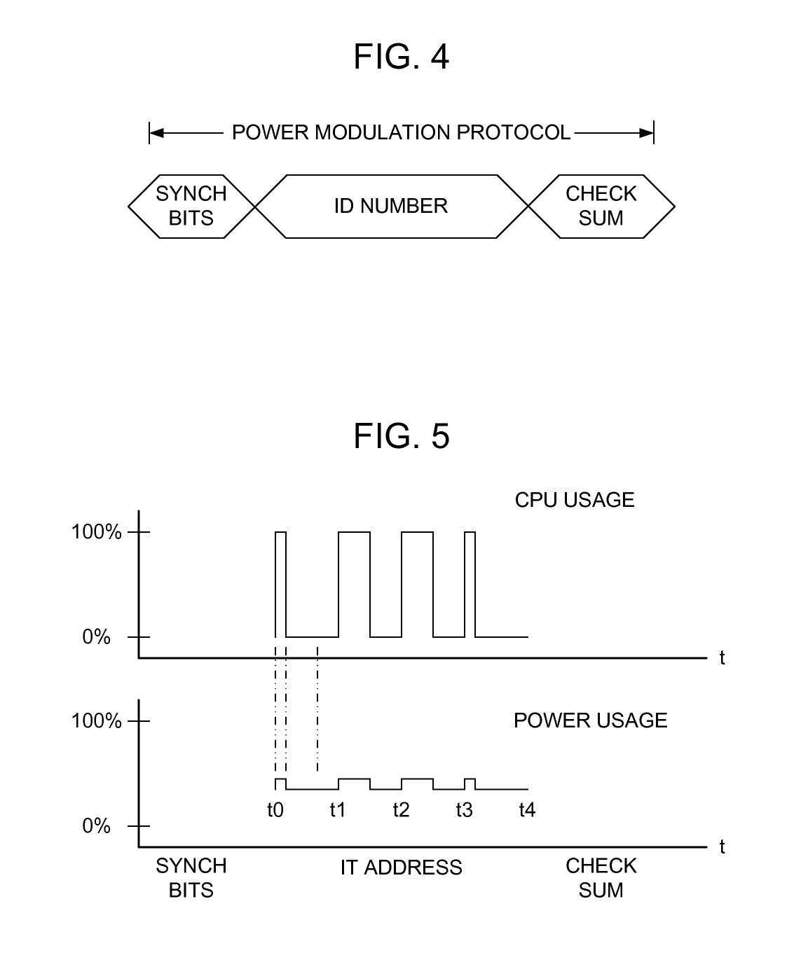

Next, the software 138 operates to cause the power usage of the load ITi to vary (to be modulated) as a function of the ID number (action 206). The power usage of the load ITi is an indicator and/or parameter associated with the power actually drawn by the load ITi from the PDU 102. In order to facilitate the ability to interpret the modulation in a useful way, it is preferred that the modulation be performed in accordance with a predetermined protocol. One example of a suitable modulation protocol is illustrated in FIG. 4, and includes synchronization bits, the ID number, and a check summation (checksum). Although a number of known techniques are available to the artisan to implement the illustrated protocol (and/or any number of alternative protocols), one approach is to define the synchronization bits to be a particular (and preferably unlikely) string of logic states (bits, which are logic 1's and 0's) that serves as an indicator that decodable information is to follow. Next, the protocol may define a particular number of logical states (bits), following the synchronization bits, to represent the ID number. In the case of using the Ethernet MAC address of the load ITi as the ID number, the next 48 bits would be defined to represent the ID number. Lastly, the protocol may define a particular number of logical states (bits), following the ID number, to define a checksum. Although any number of known techniques may be employed to define and produce the checksum, a fixed-size datum is preferably computed from at least the ID number for the purpose of checking for any accidental errors that may be introduced during the modulation, transmission, and/or storage of the data produced during the process.

In order to facilitate the ability to establish and interpret each logic state (bit) of the modulation process in a useful way, it is preferred that such bits adhere to a predetermined protocol. One example of a suitable bit protocol is illustrated in FIG. 5, which shows a number of timing diagrams. The upper diagram represents a plot of CPU usage (measured in percent) as a function of time, and the lower diagram represents a plot of the power usage of the load ITi as a function of time. The CPU usage is a representation of the usage (whether instantaneous, average, peak, or other parameter) of the one or more microprocessors 130 of the load ITi, and the power usage results from the particular CPU usage. Thus, when the CPU usage approaches or reaches 100%, the power usage likewise increases. Conversely, when the CPU usage approaches or reaches 0%, the power usage likewise decreases.

Advantageously, the software 138 running during action 206 (FIG. 3) is operable to control the CPU usage of the load ITi in order to achieve the desired modulation of the power usage thereof. Thus, by controlling the CPU usage, the software 138 may cause the power usage of the load ITi to increase and decrease to represent respective characters (bits) or groups of bits of the synchronization bits, the ID number, and the checksum (assuming all are employed). The bit protocol may be defined by an artisan in any number of ways. In a preferred embodiment, a bit is represented by a particular level and/or change of level(s) of the power usage during a fixed interval of time. For example, a first predetermined level and/or pattern in the power usage may represent a logic 1, while a second predetermined level and/or pattern in the power usage may represent a logic 0.

In the illustrated example, each bit is represented in a fixed interval of 2 seconds and bit information is provided by way of the pulse width in each interval (i.e., pulse width modulation). As shown between time=t0 through t1, a logic 0 is represented and modulated by a high level (e.g., about 100% CPU usage, 35% power usage) for a relatively short period of time (e.g., 100 ms) followed by a low level (e.g., about 0% CPU usage, 15%power usage) for a relatively long period of time (e.g., 1.9 seconds). As shown between time=t1 through t2, a logic 1 is represented and modulated by a high level (e.g., about 100% CPU usage, 35% power usage) for about half the interval (e.g., about 1.0 second) followed by a low level (e.g., about 0% CPU usage, 15%power usage) for about the remaining half of the interval (e.g., another 1.0 second). From time=t2 through t3, a logic 1 is modulated and from time=t3 through t4 a logic 0 is modulated. Thus, in this example, the ID number is: 0, 1, 1, 0. Similar techniques may be employed to modulate the power usage of the load ITi to include the synchronization bits, the ID number, and/or the checksum.

Turning again to FIG. 3, action 206, those skilled in the art will appreciate that alternative embodiments of the present invention may use the software 138 to manipulate other circuits within the load ITi (in addition to, or as an alternative to, the CPU usage) in order to modulate the power usage thereof. Although illustrated as a sequential step, it is preferred that during the modulation of the power usage of the load ITi (action 206), the PDU 102 operates to monitor such power usage (action 208). In this regard, the PDU 102 may employ the circuitry used to perform the metering function to measure the power drawn by the load ITi and store a representation thereof over time in a suitable storage medium, such as the memory 122. For example, the input/output circuit 126 of the PDU 102 may receive power usage data from voltage/current sensor(s) within the power circuits 110, switching circuits Si, and/or the receptacles Ri, digitize such data, and store same in the memory 122.

Those skilled in the art will appreciate that storing the power usage data is not a requirement to practice certain aspects of the invention; however, such storage of data is advantageous for a number of reasons that will be discussed below. Indeed, at action 210 it is desirable to detect the modulation in the power usage data of the load ITi. Although such detection may be performed in real time during the monitoring/measuring step (action 208), it is preferred that such detection of modulation be performed at a later time by reading the stored power usage data from the memory 126 and analyzing same. In this regard, it is preferred that the software program 128 of the PDU 102 be employed to perform such analysis. In particular, the software program 128 may include code suitable to execute a pattern search algorithm on the stored power usage data (which may be a continuous or substantially continuous process so long as there is power usage data yet un-analyzed). The pattern search algorithm may initially search for synchronization bits and remain in such a search mode until synchronization bits are detected. At that point, the pattern search algorithm may decode the modulation found in the power usage data following the synchronization bits in accordance with the protocols discussed above with reference to FIGS. 4 and 5. A valid ID number is preferably verified only when valid synchronization bits are followed by an ID number that is followed by a valid checksum.

Since the power usage data may be associated with a particular output (receptacle Ri) of the PDU 102 (e.g., during monitoring and storage of the data), the detected ID number may also be associated with such output of the PDU 102. In this way, a number of conclusions may be drawn from the analysis. For example, a high level of confidence may be assumed that a particular, known, piece of IT equipment is connected to a particular, known PDU and/or a particular, known outlet of such PDU. Consequently, valid conclusions may be drawn as to the status of a particular piece of IT equipment based on the gathered metering data. For example, the status may include that a good power connection exists between the PDU and the piece of IT equipment, that the piece of IT equipment is drawing power from the PDU as would be expected under the circumstances, etc. Advantageously, the conclusions as to the particular connectivity between known PDUs and known pieces of IT equipment may be obtained and documented automatically through execution of the computerized process discussed above.

As concerns the hardware and software illustrated in the drawings and discussed above, the methods and apparatus disclosed and described may be implemented utilizing any of the known and available hardware, utilizing any of the known technologies, such as standard digital circuitry, any of the known processors that are operable to execute software and/or firmware programs, one or more programmable digital devices or systems, such as programmable read only memories (PROMs), programmable array logic devices (PALs), etc. Furthermore, although the apparatus illustrated in the figures are shown as being partitioned into certain functional blocks, such blocks may be implemented by way of separate circuitry and/or combined into one or more functional units. Still further, the various aspects of the invention may be implemented by way of software and/or firmware program(s) that may be stored on suitable storage medium or media (such as disk(s), memory chip(s), etc.) for transportability and/or distribution.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method, comprising:
detecting an identification (ID) number associated with a piece of information technology (IT) equipment using a first computer-readable and executable program running on the piece of IT equipment; and
modulating a power usage of the piece of IT equipment as a function of the ID number using the first program running on the piece of IT equipment.

2. The method of claim 1, wherein the step of modulating includes causing the power usage of the piece of IT equipment to increase and decrease to represent respective characters or groups of characters of the ID number.

3. The method of claim 2, wherein:
the characters of the ID number include a plurality of logic bits, which include logic 1's and 0's; and
the step of modulating includes causing the power usage of the piece of IT equipment to increase and decrease to represent the respective bits or groups of bits of the ID number.

4. The method of claim 3, wherein the step of modulating includes causing the power usage of the piece of IT equipment to:
increase and decrease in a first predetermined pattern to represent a logic 1; and
increase and decrease in a second predetermined pattern to represent a logic 0.

5. The method of claim 1, wherein the step of modulating the power usage of the piece of IT equipment as a function of the ID number includes correspondingly causing a usage level of one or more circuits of the piece of IT equipment to increase and decrease using the first program running on the piece of IT equipment.

6. The method of claim 5, wherein the one or more circuits include one of more central processing units (CPU's) of the piece of IT equipment.

7. The method of claim 1, wherein the step of modulating the power usage of the piece of IT equipment is commenced upon entering a service interval of the piece of IT equipment, which is outside a production environment thereof.

8. The method of claim 1, further comprising:
monitoring the power usage of the piece of IT equipment using a power distribution unit (PDU) that provides operating power to the piece of IT equipment; and
detecting modulation in the power usage of the piece of IT equipment caused by the first program running on the piece of IT equipment, such detection being performed using a second computer-readable and executable program running on the PDU.

9. The method of claim 8, further comprising detecting the ID number associated with the piece of IT equipment by analyzing the modulation in the power usage using the second program.

10. The method of claim 9, further comprising:
associating the ID number of the piece of IT equipment with the PDU or a particular power output receptacle of the PDU; and
storing data indicative of the association of the ID number and the PDU, or the particular power output receptacle of the PDU, in a computer-readable storage medium using the second program.

11. The method of claim 8, further comprising:
storing power usage data indicative of variations in the power usage of the piece of IT equipment within a computer-readable storage medium of the PDU; and
reading the power usage data, detecting the variations therein, and determining the ID number associated with the piece of IT equipment based on such variations, using the second program.

12. An apparatus, comprising:
a piece of information technology (IT) equipment, including at least one central processing unit (CPU), and at least one computer-readable storage medium;
a computer-readable and executable program running on the piece of IT equipment and causing the at least one CPU to execute actions, including:
detecting an identification (ID) number associated with the piece of IT equipment; and
modulating a power usage of the piece of IT equipment as a function of the ID number.

13. The apparatus of claim 12, wherein:
the ID number includes a plurality of logic 1 and logic 0 bits;
the program causes the at least one CPU to increase and decrease the power usage of the piece of IT equipment in a first predetermined pattern to modulate the power usage in such a way as to represent a logic 1; and
the program causes the at least one CPU to increase and decrease the power usage of the piece of IT equipment in a second predetermined pattern to modulate the power usage in such a way as to represent a logic 0.

14. The apparatus of claim 13, wherein the program causes the at least one CPU to increase and decrease usage in order to modulate the power usage of the piece of IT equipment.

15. An apparatus, comprising:
a power distribution unit (PDU), including at least one central processing unit (CPU), at least one computer-readable storage medium, and at least one power output receptacle for providing operating power to a piece of information technology (IT) equipment;
a monitoring circuit disposed within the PDU and operating to measure a power usage of the piece of IT equipment drawn through the at least one power output receptacle; and
a computer-readable and executable program running on the PDU and causing the at least one CPU to execute actions, including:
detecting modulation in the power usage of the piece of IT equipment; and
detecting an identification (ID) number associated with the piece of IT equipment by analyzing the modulation in the power usage using the program.

16. The apparatus of claim 15, wherein:
the ID number of the piece of IT equipment includes a plurality of logic 1 and logic 0 bits;
the IT equipment increases and decreases it's power usage in a first predetermined pattern to modulate the power usage in such a way as to represent logic l′s of the ID number; and
the IT equipment increases and decreases it's power usage in a second predetermined pattern to modulate the power usage in such a way as to represent logic 0's of the ID number.

17. The apparatus of claim 16, wherein the computer-readable and executable program running on the PDU causes the at least one CPU to execute actions, including:
associating the ID number of the piece of IT equipment with the PDU or the power output receptacle of the PDU; and
storing data indicative of the association of the ID number and the PDU, or the power output receptacle of the PDU, in the computer-readable storage medium.

18. An apparatus, comprising:
a piece of information technology (IT) equipment, including:
at least one central processing unit (CPU),
at least one computer-readable storage medium, and
a first computer-readable and executable program running on the piece of IT equipment and causing the at least one CPU to execute actions, including:
detecting an identification (ID) number associated with the piece of IT equipment, and
modulating a power usage of the piece of IT equipment as a function of the ID number,
a power distribution unit (PDU), including:
at least one central processing unit (CPU),
at least one computer-readable storage medium,
at least one power output receptacle for providing operating power to the IT equipment,
a monitoring circuit disposed within the PDU and operating to measure the power usage of the piece of IT equipment drawn through the at least one power output receptacle, and
a computer-readable and executable program running on the PDU and causing the at least one CPU to execute actions, including:
detecting modulation in the power usage of the piece of IT equipment; and
detecting the ID number associated with the piece of IT equipment by analyzing the modulation in the power usage using the program.

19. The apparatus of claim 18, wherein:
the ID number includes a plurality of logic 1 and logic 0 bits;
the first program causes the at least one CPU of the IT equipment to increase and decrease the power usage of the piece of IT equipment in a first predetermined pattern to modulate the power usage in such a way as to represent a logic 1;
the first program causes the at least one CPU of the IT equipment to increase and decrease the power usage of the piece of IT equipment in a second predetermined pattern to modulate the power usage in such a way as to represent a logic 0 and;
the first program causes the at least one CPU to increase and decrease usage in order to modulate the power usage of the piece of IT equipment.

20. The apparatus of claim 19, wherein the second computer-readable and executable program running on the PDU causes the at least one CPU thereof to execute actions, including:
associating the ID number of the piece of IT equipment with the PDU or the power output receptacle of the PDU; and
storing data indicative of the association of the ID number and the PDU, or the power output receptacle of the PDU, in the computer-readable storage medium.
